(19) United States
(12) Patent Application Publication
(10) Pub. No.: US 2021/0193231 A1
(43) Pub. Date: Jun. 24, 2021

(54) MANAGING READ VOLTAGE LEVEL OF DATA UNITS IN A MEMORY DEVICE USING PROGRAM-TIME PROXIMITY

(71) Applicant: Micron Technology, Inc., Boise, ID (US)

(72) Inventors: Ting Luo, Santa Clara, CA (US); Chun Sum Yeung, San Jose, CA (US)

(21) Appl. No.: 16/807,739

(22) Filed: Mar. 3, 2020

Related U.S. Application Data
(60) Provisional application No. 62/951,786, filed on Dec. 20, 2019.

(51) Int. Cl. G11C 16/26; G06F 3/06; G11C 16/10

(52) U.S. Cl. CPC G11C 16/26; G06F 3/0604; G11C 16/0483; G06F 3/0679; G11C 16/10; G06F 3/0659

(57) ABSTRACT

A processing device, operatively coupled with the memory device, is configured to receive a read request identifying data stored in a data unit of the memory device. The processing device further identifies a set of data units with which the data unit is associated, the set of data units is one of a plurality of sets of data units, and each data unit in the set of data units was programmed within a period of time associated with the set of data units. The processing device also determines a read voltage level of the set of data units, each of the plurality of sets of data units has a separate read voltage level. The processing device further performs a read operation on the data unit of the memory device using the read voltage level of the set of data units.

### RELATED APPLICATIONS

This application claims benefit under 35 U.S. C. § 119(e) of U.S. Provisional Patent Application No. 62/951,786, filed Dec. 20, 2019, which is incorporated herein by this reference in its entirety.

### TECHNICAL FIELD

The present disclosure generally relates to memory sub-systems, and more specifically, relates to managing read voltage level of data units in a memory device using program-time proximity of the data units.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system for supporting multiple read voltage levels for data units in a memory sub-system, in accordance with some embodiments of the present disclosure.

FIG. 2 is a block diagram illustrating the assignment of data units in a memory device to sets of data units, in accordance with some embodiments of the present disclosure.

FIG. 3 illustrates an example timeline for creating sets of data unis and assigning data units to sets of data units in support read voltage level management, in accordance with some embodiments of the present disclosure.

FIG. 4 is a flow diagram of an example method of managing multiple read voltage level values for sets of data units in a memory sub-system, in accordance with some embodiments of the present disclosure.

FIG. 5 is a flow diagram of an example method of determining a read voltage level for a set of data units in a memory sub-system, in accordance with some embodiments of the present disclosure.

FIG. 6 is a flow diagram of an example method of performing read operations using different read voltage level values from sets of data units in a memory sub-system, in accordance with some embodiments of the present disclosure.

FIG. 7 is a block diagram of an example computer system in which embodiments of the present disclosure can operate.

### DETAILED DESCRIPTION

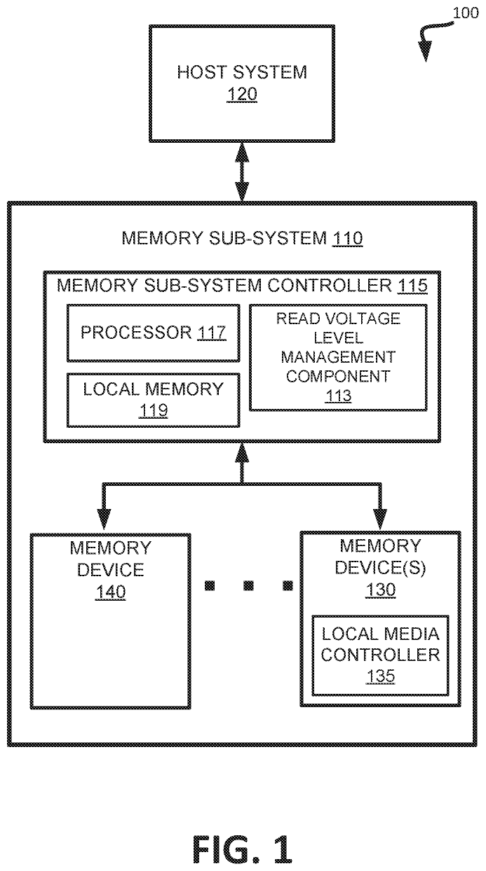

Aspects of the present disclosure are directed to managing separate read voltage levels when performing read operations of data stored in memory devices of a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more memory devices that store data. The host system can provide data to be stored at the memory sub-system and can request data to be retrieved from the memory sub-system.

A memory sub-system can include multiple memory devices that can store data from a host system. A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1. The dice in the packages can be assigned to one or more channels for communicating with a memory sub-system controller. Each die can consist of one or more planes. Planes can be groups into logic units (LUN). For some types of non-volatile memory devices (e.g., NAND memory devices), each plane consists of a set of physical blocks, which are groups of memory cells to store data. A cell is an electronic circuit that stores information.

When data is written to and/or erased from a memory cell of a memory device, the memory cell can be damaged to some extent. As the number of write operations and/or erase operations performed on a memory cell increases, the probability of the data stored at the memory cell including an error increases, and the memory cell is increasingly damaged. An increasing number of read and write operations can result in a higher error rate of the data stored at the memory cells. This can increase the use of error recovery operations, which includes but not is limited to a read error handling module (REH) that can recover data as well as determine a passing read voltage level for the memory cells being read. A passing read voltage level can refer to a read voltage level that, when used in a read operation generates an error indicator within an acceptable range, causing the read operation to succeed. Additionally, memory cells that are programmed at significantly different times can require a different read voltage level for a successful read of the data stored at the memory cells. Thus as the memory sub-system processes read operations from the various memory cells, the memory sub-system may trigger the REH module more frequently in order to obtain a passing read voltage level for the memory cell(s) being read. The increased use of the error recovery operations can result in a reduction of the performance of a conventional memory sub-system. In addition, as the error rate continues to increase, it may even surpass the error recovery capabilities of the memory sub-system, leading to an irreparable loss of the data. Furthermore, as more resources of the memory sub-system are used to perform the error recovery operations, fewer resources are available to perform other read operations or write operations.

For certain memory types (i.e., for memory sub-systems employing certain types of storage media), the error rate can vary over time. In particular, some non-volatile memories have threshold voltage (Vt) distributions that move as a function of time. At a given read level (i.e., the voltage applied to a memory cell as part of a read operation), if the Vt distributions move, then certain reliability statistics can also be affected. One example of a reliability statistic is a raw bit error rate (RBER). The RBER can be defined as the ratio of the number of erroneous bits to the number of all data bits stored in a data unit of the memory sub-system, where the data unit can be the entire memory sub-system, a die of a memory device, a collection of codewords, a collection of memory device pages, a collection of memory device blocks, or any other meaningful portion of the memory sub-system. For any Vt distribution at an instance in time, there can be an optimal read voltage level (or read level range) that minimizes the expected RBER. In particular, the Vt distribution and RBER can be a function of the time since the data unit was programmed (i.e., the period of time that passes since data was written to the data unit). Due to this time-varying nature of RBER, as well as other noise mechanisms in memory, a single read voltage level may not be sufficient to achieve an error rate that satisfies certain system reliability targets.

Accordingly, certain memory sub-systems can require a number of pre-programmed read voltage levels, each corresponding to a set of data units that were programmed close in time to each other, in order to minimize the execution of error recovery operations. This is particularly desired in memory devices where the voltage distribution of the data units is shifting frequently (e.g., a replacement gate NAND memory device), the passing read voltage level can vary significantly based on the time a data unit was programmed. For example, a first read voltage level may be used to read data having a first range of time since programmed, while a second read voltage level may be used to read data having a second range of time since programmed.

Aspects of the present disclosure address the above and other deficiencies by assigning a separate read voltage level to each set of data units that were programmed within a predetermined time period. In this case, the memory sub-system can have multiple sets of data units and each set of data units can have a dedicated read voltage level that can be used to perform read operations of data stored at the data units of the respective set. In implementations, data units that are programmed close in time to each other can be included in or assigned to the same set of data units, and thus the same read voltage level can be used to perform read operations of data stored at the data units. Conversely, if two data units are programmed at two different times that are farther apart, the two data units can be assigned to two different sets of data units. Thus a different read voltage level associated with each respective set of data units can be used to perform read operations of data stored at each data unit.

In certain implementations, the memory sub-system can create sets of data units at data unit program time, and can keep one set of data units as the current set of data units for a predetermined period of time (e.g., two hours). Any data unit that is programmed during the predetermined period of time can be assigned to the current set of data units. When the predetermined period of time elapses, the memory sub-system can create a new set of data units and can start assigning data units that are programmed within the second period of time to the new set of data units, and so on. In certain implementations, when data stored at a data unit is erased (e.g., to enable a re-write of the data unit), the data unit can be removed from the set of data units to which the data unit was assigned when the data unit was programmed.

When a set of data units is created, it can be associated with one or more data units. The set of data units can be assigned a read voltage level when a read operation is received, requesting data that is stored at one of the data units in the set of data units. In this case, when the read operation is received, the memory sub-system can check if the set of data units has an associated read voltage level. If the set of data units does not have an associated read voltage level yet, the memory sub-system can determine a read voltage level for the set of data units and can assign the determined read voltage level to the set of data units. Subsequent read operations for data units associated with the set of data units can use the read voltage level assigned to the set to perform the read operations of data stored at data units within he set of data units.

In an implementation, the read voltage level assigned to a set of data units can cause read operations to fail, for example due to shifting in the voltage distribution of memory cells of the data units. When such shifting of the voltage distribution occurs for a data unit, the read voltage level that is associated with the data unit can be updated to reflect a passing read voltage level for the set of data units. In implementations, the memory sub-system can use an error handling module in order to obtain a new read voltage level value. The new read voltage level value can then be assigned to the set of data units, replacing the previous read voltage level. Subsequent read operations for data units associated with the set of data units can then use the new read voltage level when performing the read operations.

The techniques of supporting multiple read voltage levels for multiple sets of data units in a memory sub-system described herein enables an improved overall performance of the memory sub-system. In memory devices where the voltage distribution of memory cells is shifting frequently (e.g., replacement gate NAND memory device), the passing read voltage level can vary significantly based on the time a data unit was programmed. Therefore, by having a separate read voltage level for each set of data units that were programmed close in time to each other (e.g., within a predetermined period of time), read operations of the data units can reuse the passing read voltage level, without having to trigger a time consuming read error handling module to correct the read voltage level as often. Because the memory sub-system is no longer using a single read voltage level value for the whole memory device, the need to execute a costly read error handling module can be reduced significantly as more sets of data units are created within the memory sub-system. Therefore, the techniques described herein of supporting a separate read voltage level for each set of data units reduce the overhead of frequently executing the read error handling module, which improves the overall performance of the memory sub-system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory. A 3D cross-point memory device is a cross-point array of non-volatile memory cells that can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric random access memory (FeRAM), ferroelectric transitor random-access memory (FeTRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory sub-system 110 includes read voltage level component 113 that can be used to support a separate read voltage level for separates sets of data units based on proximity in programming time of the data units. In implementations, read voltage level component 113 can create multiple sets of data units of memory devices 130-140. Each set of data units can have an associated read voltage level that can be used to perform read operations of data stored at the data units of the respective set. In implementations, data units that are programmed close in time to each other can be included in or assigned to the same set of data units, and thus the same read voltage level can be used to perform read operations of data stored at the data units. Conversely, if two data units are programmed at two different times that are farther apart (e.g., are programmed at times on opposite sides of a threshold time), the two data units can be assigned to two different sets of data units. Thus a different read voltage level associated with each respective set of data units can be used to perform read operations of data stored at each data unit. In implementations, the memory sub-system can store the read voltage level associated with each set of data units in memory sub-system controller 115 of memory sub-system 110.

In certain implementations, read voltage level component 113 can create the sets of data units at data unit program time, and can keep one set of data units as the current set of data units for a predetermined period of time. Any data unit that is programmed during the predetermined period of time can be assigned to the current set of data units. For example, when memory sub-system 110 is powered up, read voltage level component 113 can create a first set of data units. The first set can be the designated current set of data units for a predetermined time period that can be determined based on the specification of memory sub-system 110 (e.g., four hours). In this case, each data unit that is programmed within the four hours, from the time of powering up the memory sub-system to the end of the predetermined time period, can be assigned to the first set of data units. When the four hours elapse, the memory sub-system can create a new set of data units and can start assigning data units that are programmed within the second period of four hours to the new set of data units, and so on. In certain implementations, when data stored at a data unit is erased (e.g., to enable a re-write of the data unit), the data unit can be removed from the set of data units to witch the data unit was assigned when the data unit was programmed.

When a set of data units is created, it can be associate with one or more data units. The set of data units can be assigned a read voltage level when a read operation is received, requesting data that is stored at one of the data units in the set of data units. In this case, when the read operation is received, read voltage level component 113 can check if the set of data units has an associated read voltage level. If the set of data units already has an associated read voltage level, read voltage level component 113 can use the read voltage level associated with the set of data units to perform the read operation. On the other hand, if the set of data units does not have an associated read voltage level yet, read voltage level component 113 can use a default read voltage level to perform the read operation. In certain implementations, because the voltage distribution of data units is shifting over time, the default read voltage level can cause the read operation to fail (e.g., the read operation will generate a read bit error rate (RBER) that is higher than a certain threshold). When the read operation that is performed using the default read voltage error fails, read voltage level component 113 can trigger a read error handling (REH) module in order to recover data and to determine a new value of read voltage error that is more suitable for the specific data unit being read. Subsequently, read voltage level component 113 can use the new read voltage level determined by the REH module to perform the read operation again. If the read operation is performed successfully, read voltage level component 113 can assign the new read voltage level to the set of data units to which the read data unit has been assigned. Subsequent read operations for data units associated with the set of data units can use the read voltage level assigned to the set to perform the read operations of data stored at data units within he set of data units.

In an implementation, the read voltage level assigned to a set of data units can cause read operations to fail, for example due to shifting in the voltage distribution of memory cells constituting the data units. Shifting in voltage distribution of memory cells can be due to a number of factors including temperature, repeated program/erase operations, and the passage of time since memory cells where programmed. When such shifting of voltage distribution occurs for a data unit, the read voltage level that is associated with the data unit (via the set of data units to witch the data unit is assigned) may no longer be valid. In this case, a read operation of the data unit using the associated read voltage level can fail. As explained above, a failed read operation can trigger a REH module in order to obtain a new read voltage level value. The new read voltage level value can then be used to perform the read operation again. When the second read operation is performed successfully, read voltage level component 113 can assign the new read voltage level to the set of data units, replacing the previous read voltage level. Subsequent read operations for data units associated with the set of data units can then use the new read voltage level when performing the read operations.

In certain implementations, in order to maintain a manageable number of the sets of data units, read voltage level component 113 can merge sets of data units together, such that data units belonging to multiple sets can be merged together under just one set of data units. In implementations, older sets of data units (e.g., that were created several months ago) can have similar read voltage level values, and thus can be merged together into one set of data units. For example, read voltage level component 113 can determine that sets of data units having read voltage level values within certain proximity of each other can be merged together into one set. In an illustrative example, if the difference between the read voltage level values of two sets of data units is small enough to satisfy a threshold condition, read voltage level component 113 can merge the data units within the two sets into one set of data units, encompassing all the data units of both sets. In this case, read voltage level component 113 can assign the read voltage level of one of the sets of data units before the merge to the resulting set of data units after the merge.

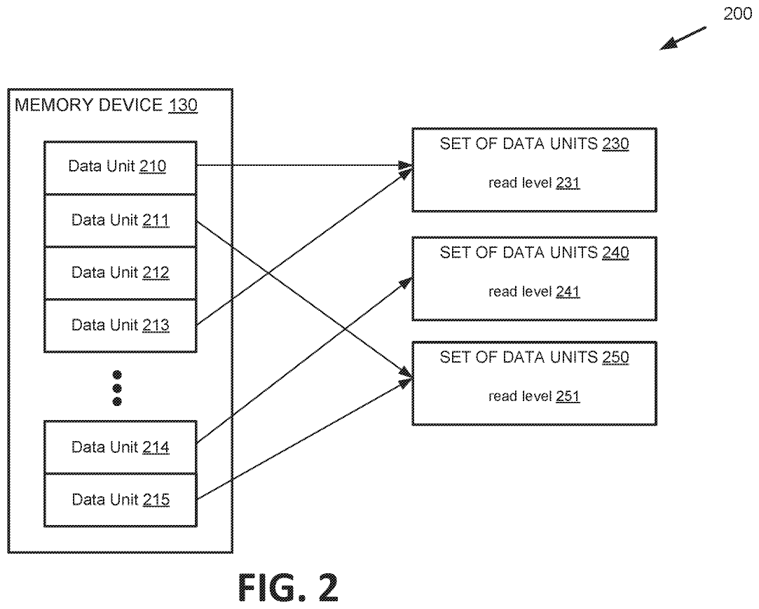

FIG. 2 is a block diagram 200 illustrating the assignment of data units in a memory device to sets of data units, in accordance with some embodiments of the present disclosure. In one implementation, memory device 130 can include data units 210-215, and each data unit can be programmed at a different time. Each memory device 130-140 of FIG. 1 can contain hundreds of data units. A data unit can refer to a unit of a memory device used to store data and can include one or more memory pages, one or more memory blocks, one or more memory cells, or one or more word lines.

In one implementation, multiple sets of data units 230-250 can be defined in memory sub-system 110, and each set of data units 230-250 can include a separate read voltage level 231, 241, and 251. FIG. 2 illustrates an example where there are three sets of data units 230-250. Each data unit 210-215 can be assigned to only one of set of data units 230-250, depending on the time that each data unit was programmed. In an implementation, the processing logic can create set of data units 230, e.g., when memory sub-system 110 powers up, and can designate set of data units 230 as the current set for a predetermined period of time (e.g., two hours). All data units that are programmed during the time period where set of data units 230 is current will be assigned to set of data units 230 (e.g., data units 210 and 213). Similarly, set of data units 240 can be created at a different point in time and can be designated as the current set of data units for the same duration of time (e.g., two hours). Data units that are programmed when set of data units 240 is current will be assigned to set of data units 240 (e.g., data unit 214). Set of data units 250 can further be created at yet another point in time and can be designated as the current set of data units for a thirds period of 2 hours. Data units that are programmed during the third period of two hours will be assigned to set of data units 250 (e.g., data units 211 and 215), and so on.

Referring to FIG. 2, data unit 210 and data unit 213 are assigned to set of data units 230, indicating the data units 210 and 213 were programmed closer in time to each other. Therefore, when a read operation is received at memory sub-system 110 for data stored at data unit 210 or at data unit 213, memory sub-system 110 can use read voltage level 231 of set 230 to perform the read operation. For example, when memory sub-system 110 receives a read operation of data stored at data unit 210, memory sub-system 110 can search the available sets of data units to determine which set of data units is associated with data unit 210. When memory sub-system 110 determines that data unit 210 is assigned to set 230, memory sub-system 110 can retrieve read voltage level 231 that is associated with set 230 and can perform the read operation using read voltage level 231.

Data unit 214 is assigned to set of data units 240, indicating the data units 214 was programmed at a time where set of data units 240 was the current set. Therefore, when a read operation is received at memory sub-system 110 for data stored at data unit 214, memory sub-system 110 can use read voltage level 241 of set 240 to perform the read operation. For example, when memory sub-system 110 receives a read operation of data stored at data unit 214, memory sub-system 110 can search the available sets of data units to determine which set of data units is associated with data unit 214. When memory sub-system 110 determines that data unit 214 is assigned to set 240, memory sub-system 110 can retrieve read voltage level 241 that is associated with set 240 and can perform the read operation using read voltage level 241.

Data unit 211 and data unit 215 are assigned to set of data units 250, indicating the data units 211 and 215 were programmed closer in time to each other. Therefore, when a read operation is received at memory sub-system 110 for data stored at data unit 211 or at data unit 215, memory sub-system 110 can use read voltage level 251 of set 250 to perform the read operation. For example, when memory sub-system 110 receives a read operation of data stored at data unit 215, memory sub-system 110 can search the available sets of data units to determine which set of data units is associated with data unit 215. When memory sub-system 110 determines that data unit 215 is assigned to set 250, memory sub-system 110 can retrieve read voltage level 251 that is associated with set 250 and can perform the read operation using read voltage level 251.

Data unit 212 is not associated with a set of data units. In an implementation, this can indicate that data unit 212 has not been programmed with any data yet. In this case, data unit 212 will not be assigned to a set of data units. When memory sub-system 110 received a program operation targeting data unit 212, memory sub-system 110 can then perform the program operation and can assign data unit 212 to the set of data units that is the current set at the time of programming data unit 212.

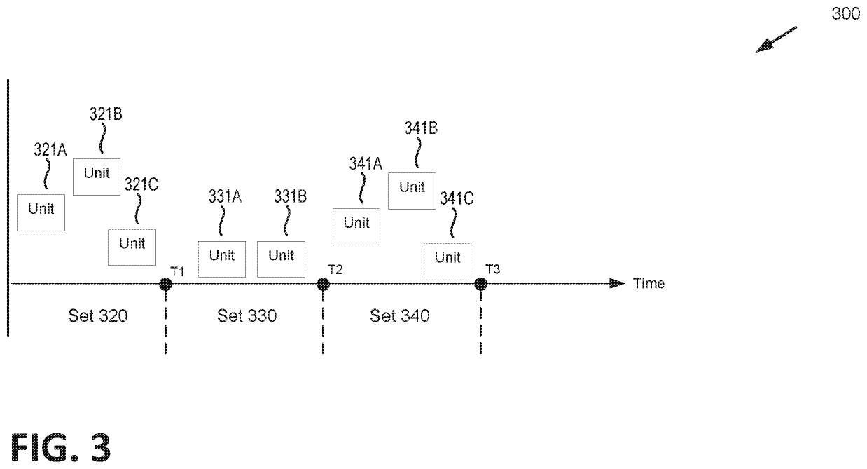

FIG. 3 illustrates an example timeline for creating sets of data unis and assigning data units to sets of data units in support read voltage level management, in accordance with some embodiments of the present disclosure. In certain implementations, memory sub-system 110 can start creating sets of data units and start assigning data units to the multiple sets of data units when memory sub-system 110 powers up. Memory sub-system 100 can then designate one set of data units as the current set at a time. The current set of data units continues to be current for a predetermined period of time (e.g., two hours), after which another set of data units is created and is designated as the current set of data units, and so on. As data units get programmed they get assigned to the current set of data units at the time of programming the data unit.

In an illustrative example, set 320 can be created when memory sub-system 110 powers up, for example at 9:00 am. Assuming that the predetermined period of time (T1) is 2 hours, then set 320 will be the designated current set of data units until T1 elapses, for example at 11:00 am. In this example, memory sub-system 110 can receive three program requests for programming data into data unit 321A, 321B, and 321C respectively. The three program requests are received between 9:00 AM and 11:00 AM, during which set 320 is the current set of data units. Thus, after performing the program operation on the respective data unit, the memory sub-system can assign each of data units 321A-C to set 320. At T1=11:00 am, memory sub-system 110 can create a new set of data units 330 and can designate set 330 as the current set of data units until T2=1:00 pm.

Similarly, memory sub-system 110 can receive two program requests for programming data into data unit 331A and 331B. The two program requests are received between 11:00 AM and 1:00 PM, during which set 330 is the current set of data units. Thus, each of data units 331A-B is assigned to set 330 when its respective program operation is performed. At T2=1:00 PM, memory sub-system 110 can create a new set of data units 340 and can designate set 340 as the current set of data units until T3=3:00 PM.

At T2, memory sub-system 110 can receive three program requests for programming data into data unit 341A, 341B, and 341C respectively. The three program requests are received between 1:00 PM and 3:00 PM, during which set 340 is the current set of data units. Thus, each of data units 341A-C is assigned to set 340 when its respective program operation is performed. At T13=3:00 PM, memory sub-system 110 can create a new set of data units (not shown) and can designate the new set as the current set of data units, and so on.

In implementations, when data stored at one of data units 321A-C, 331A-B, and 341A-C is erased (e.g., to enable a re-write of the data unit), the erased data unit can be removed from the corresponding set of data units to witch the erased data unit was assigned when the data unit was programmed. Therefore, when the erased data unit is programmed again it can be assigned to a different set of data units, based on the time of the program operation.

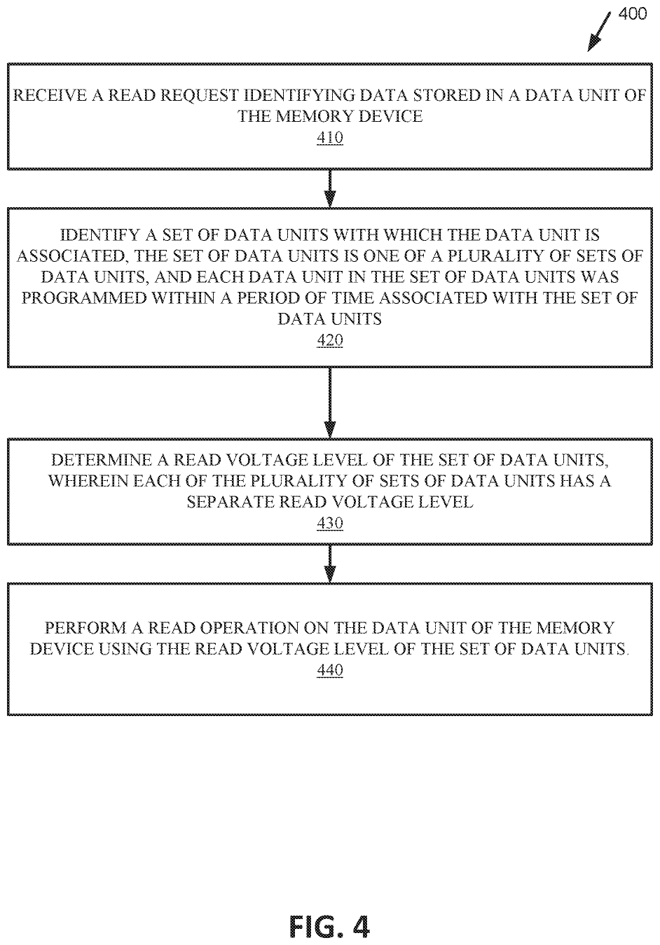

FIG. 4 is a flow diagram of an example method of managing multiple read voltage level values for sets of data units in a memory sub-system, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by read voltage level management component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, the processing logic receives a read request identifying data stored in a data unit of the memory device. In implementations, the read request can be received from a host system. In other implementations, the read request can be received from the memory sub-system controller, for example, to perform a wear leveling operation, a garbage collection operation, etc. In order to execute the read request, a read operation can be performed using a read voltage level value associated with a set of data units to which the data unit is assigned, as explained in details herein.

At operation 420, the processing logic identifies a set of data units with which the data unit is associated. The set of data units is one of multiple sets of data units within the memory sub-system and each data unit in the set of data units was programmed within a period of time associated with the set of data units. In implementations, the set of data units can be identified by matching an identifier of the data unit with a list of identifiers of data units associated with the set of data units.

At operation 430, the processing device determines a read voltage level of the set of data units. In implementations, each set of data units of the multiple sets of data units of the memory sub-system a separate read voltage level. In certain implementations, a read voltage level can of a set of data units can be determined using a read error handling module, and then can be assigned to the set of data units, as explained in more details herein above.

At operation 440, the processing device performs a read operation on the data unit of the memory device using the read voltage level of the set of data units. In implementations, if the read operation fails (e.g., due to shifting of the voltage distribution of memory cells constituting the data unit) the processing device can trigger a REH module in order to obtain a new read voltage level value. The new read voltage level value can then be used to perform the read operation again. When the second read operation is performed successfully, the processing logic can assign the new read voltage level to the set of data units, replacing the previous read voltage level, as explained in more details herein.

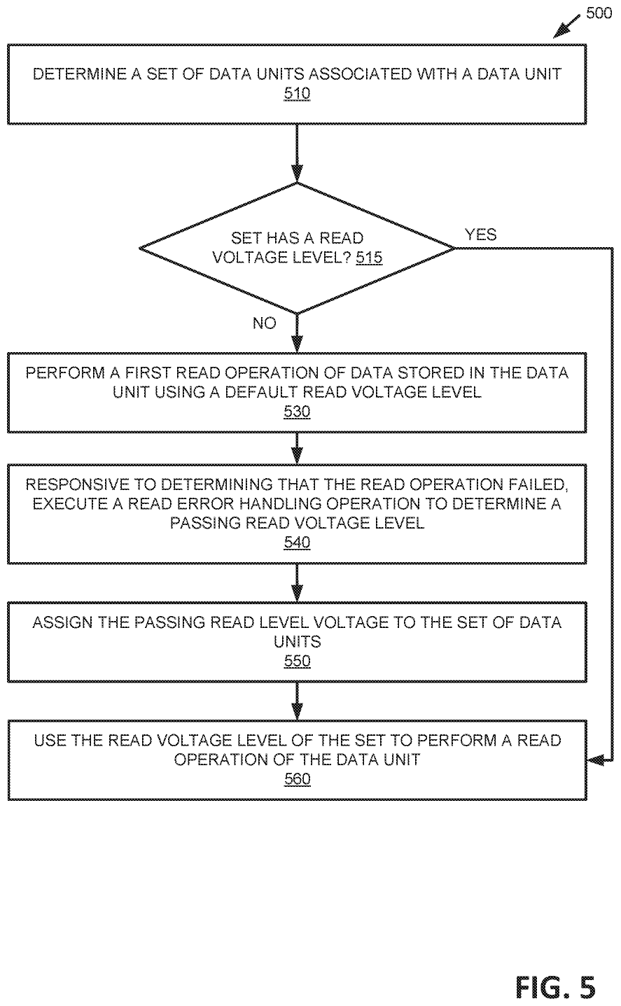

FIG. 5 is a flow diagram of an example method of determining a read voltage level for a set of data units in a memory sub-system, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by read voltage level management component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic determines a set of data units associated with a data unit, for example, in order to perform a read operation of data in the data unit using a read voltage level from the associated set of data units, as explained in details herein.

At operation 515, the processing logic determines whether the set of data units has an assigned read voltage level. In implementations, the set of data units can have an assigned read voltage level when a read operation for data stored in any data unit associated with the set is performed, as explained in more details herein.

At operation 530, upon determining that the set does not have an assigned read voltage level, the processing logic performs a read operation of data stored in the data unit using a default read voltage level. In implementation, the default read voltage level may refer to an initial value of read voltage level that can be associated with the memory device, and not specific to any particular set of data units.

Accordingly, at operation 540, the processing logic can determine that the read operation using the default read voltage level has failed. In implementations, when performing a read operation using the default read voltage level, an indicator of the accuracy of the read operation (e.g., the read bit error rate (RBER)) can be higher than a certain threshold due to the inaccuracy of the default read voltage level. Thus, the processing logic can trigger a read error handling (REH) module to obtain a passing read voltage level for the data unit, as explained in more details herein.

At operation 550, the processing logic assigns the passing read level voltage obtained from the REH module to the set of data units. And at operation 560, the processing logic uses the read voltage level of the set to perform the read operation of the data unit. Further read operations of data stored at data units associated with the set of data units can be performed using the read voltage level associated with the set.

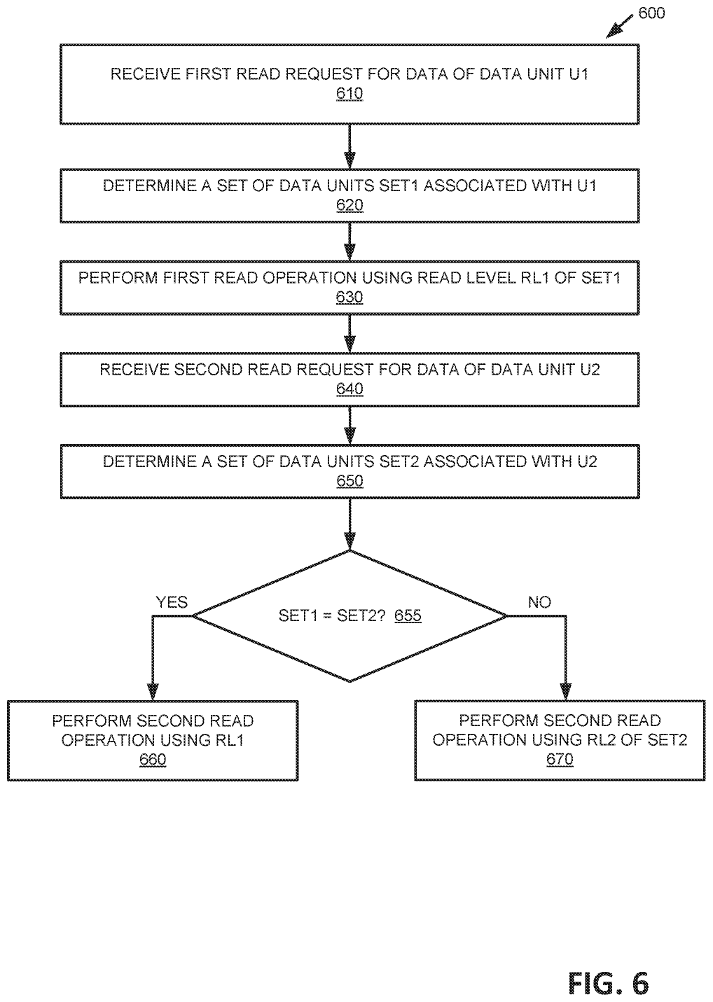

FIG. 6 is a flow diagram of an example method of performing read operations using different read voltage level values from sets of data units in a memory sub-system, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by read voltage level management component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 610, the processing logic receives a first read request for data stored at data unit U1. The processing logic then, at operation 620, determines a set of data units Set1 associated with data unit U1 in order to retrieve a read voltage level associated with set1, in order to perform the read operation.

At operation 630, the processing logic performs the first read operation using read voltage level RL1 of Set1, as explained in more details herein above. In implementations, the processing logic can determine the read voltage level of set1 using a REH module, as previously explained.

At operation 640, the processing logic receives a following read request for data stored at another data unit U2. Similarly, the processing logic determines a set of data units Set2 that is associated with data unit U2. At operation 655, the processing logic determines whether Set1 and Set2 are the same, indicating that data unit U1 and data unit U2 belong to the same set of data units. In implementations, when performing read operations of data stored at data units associated with the same set of data units, the processing logic can use the read voltage level assigned to the set of data units for performing the read operation for each data unit, as explained in more details herein above.

At operation 660, the processing device determines that data unit U1 and data unit U2 are associated with the same set of data units (Set1), the processing logic then performs the read operation of data stored at U2 using RL1 of Sett.

On the other hand, at operation 670, when the processing device determines that data unit U1 and data unit U2 are associated with different sets of data units, the processing logic performs the read operation of data stored at data unit U2 using another read voltage level RL2 of Set2.

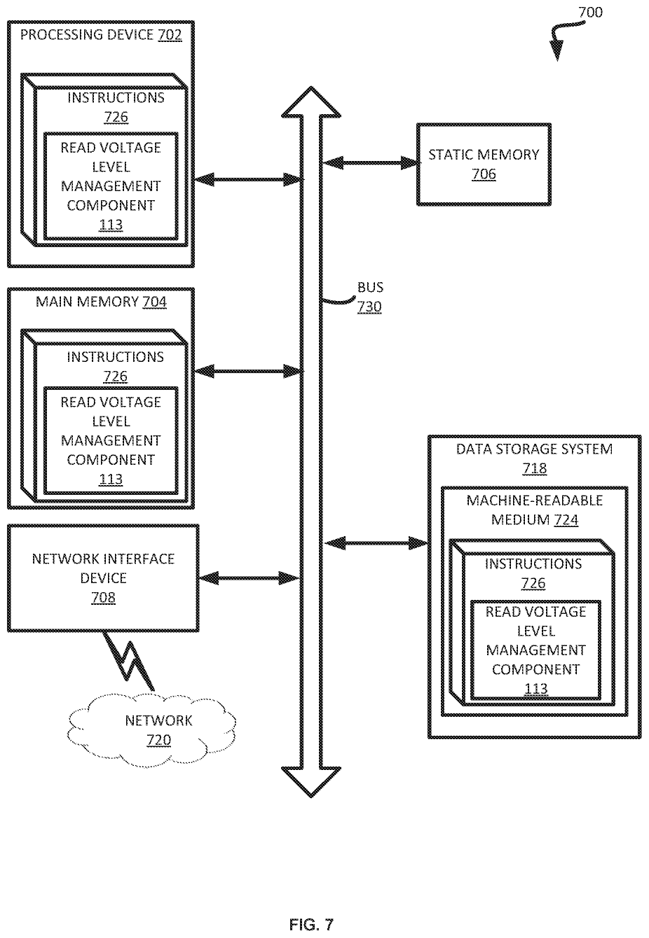

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to read voltage level management component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1.

In one embodiment, the instructions 726 include instructions to implement functionality corresponding to read voltage level management component 113 of FIG. 1. While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
receiving a read request identifying data stored in a data unit of the memory device;
identifying a set of data units with which the data unit is associated, wherein the set of data units is one of a plurality of sets of data units, and wherein each data unit in the set of data units was programmed within a period of time associated with the set of data units;
determining a read voltage level of the set of data units, wherein each of the plurality of sets of data units has a separate read voltage level; and
performing a read operation on the data unit of the memory device using the read voltage level of the set of data units.

2. The system of claim 1, wherein each of the plurality of sets of data units comprises data units that were programmed within a separate associated period of time.

3. The system of claim 1, wherein the processing device to perform further operations comprising:
receiving a program request identifying data to be stored on the memory device;
programming the data to the data unit of the memory device; and
assigning the data unit to a current set of data units, wherein the current set of data units comprises data units programmed within a current period of time.

4. The system of claim 1, wherein to determine the read voltage level of the set of data units, the processing device to perform further operations comprising:
determining whether a read voltage level is assigned to the set of data units;
responsive to determining that no read voltage level is assigned to the set of data units:
performing, using a default read voltage level, a first read operation of data stored in the data unit; and
responsive to determining that the first read operation failed:
executing a read error handling operation to determine a second read voltage level, and
assigning the second read voltage level to the set of data units.

5. The system of claim 1, wherein the processing device to perform further operations comprising:
responsive to detecting that data stored in the data unit is erased, removing the data unit from a plurality of data units assigned to the set of data units.

6. The system of claim 1, wherein the processing device to perform further operations comprising:
responsive to determining that the read operation using the read voltage level of the set of data units failed:
executing a read error handling operation to determine a third read voltage level, and
assigning the third read voltage level to the set of data units, replacing the second read voltage level.

7. The system of claim 6, wherein to determine that the read operation failed, the processing logic to perform further operations comprising:
determining that the read operation resulted in a read bit error rate (RBER) value that satisfies a threshold condition.

8. The system of claim 1, wherein the processing logic to perform further operations comprising:
receiving a second read request identifying data stored in a second data unit of the memory device;
identifying a second set of data units with which the second data unit is associated, wherein the second set of data units is the same as the set of data units; and
performing a second read operation on the second data unit of the memory device using the read voltage level of the set of data units.

9. The system of claim 1, wherein the processing logic to perform further operations comprising:
receiving a third read request identifying data stored in a third data unit of the memory device;
identifying a third set of data units with which the third data unit is associated, wherein the third set of data units is different than the set of data units;
determining a second read voltage level of the third set of data units; and
performing a third read operation on the third data unit of the memory device using the second read voltage level of the third set of data units.

10. A method comprising:
receiving a read request identifying data stored in a data unit;
identifying a set of data units with which the data unit is associated, wherein the set of data units is one of a plurality of sets of data units, and wherein each data unit in the set of data units was programmed within a period of time associated with the set of data units;
determining whether a read voltage level is assigned to the set of data units;
responsive to determining that no read voltage level is assigned to the set of units:
performing, using a default read voltage level, a first read operation of data stored in the data unit; and
responsive to determining that the first read operation failed:
executing a read error handling operation to determine a second read voltage level, and
assigning the second read level voltage to the set of data units; and
performing, using the second read voltage level, a second read operation of data stored in the data unit.

11. The method of claim 10, wherein each of the plurality of sets of data units comprises data units that were programmed within a separate associated period of time.

12. The method of claim 10 further comprising:
receiving a program request identifying data to be stored on the memory device;
programming the data to the data unit of the memory device; and
assigning the data unit to a current set of data units, wherein the current set of data units comprises data units programmed within a current period of time.

13. The method of claim 10, wherein determining the read voltage level of the set of data units further comprises:
determining whether a read voltage level is assigned to the set of data units;
responsive to determining that no read voltage level is assigned to the set of data units:
performing a first read operation, of data stored in the data unit, using a default read voltage level; and
responsive to determining that the first read operation failed:
executing a read error handling operation to determine a second read voltage level, and
assigning the second read voltage level to the set of data units.

14. The method of claim 10 further comprises:
responsive to detecting that data stored in the data unit is erased, removing the data unit from a plurality of data units assigned to the set of data units.

15. The method of claim 10 determining that the first read operation failed further comprises:
determining that the read operation resulted in a read bit error rate (RBER) value that satisfies a threshold condition.

16. A non-transitory computer-readable storage medium comprising instructions that, when executed by a processing device, cause the processing device to:
receive a read request identifying data stored in a data unit of the memory device;
identify a set of data units with which the data unit is associated, wherein the set of data units is one of a plurality of sets of data units, and wherein each data unit in the set of data units was programmed within a period of time associated with the set of data units;
determine a read voltage level of the set of data units, wherein each of the plurality of sets of data units has a separate read voltage level; and
perform a read operation on the data unit of the memory device using the read voltage level of the set of data units.

17. The non-transitory computer-readable storage medium of claim 16, wherein the processing device is further to:
receive a program request identifying data to be stored on the memory device;
program the data to the data unit of the memory device; and
assign the data unit to a current set of data units, wherein the current set of data units comprises data units programmed within a current period of time.

18. The non-transitory computer-readable storage medium of claim 16, wherein the processing device is further to:
responsive to detecting that data stored in the data unit is erased, remove the data unit from a plurality of data units assigned to the set of data units.

19. The non-transitory computer-readable storage medium of claim 16, wherein the processing logic is further to:
receive a second read request identifying data stored in a second data unit of the memory device;
identify a second set of data units with which the second data unit is associated, wherein the second set of data units is the same as the set of data units; and
perform a second read operation on the second data unit of the memory device using the read voltage level of the set of data units.

20. The non-transitory computer-readable storage medium of claim 16, wherein the processing logic is further to:
receive a third read request identifying data stored in a third data unit of the memory device;
identify a third set of data units with which the third data unit is associated, wherein the third set of data units is different than the set of data units;
determine a second read voltage level of the third set of data units; and
perform a third read operation on the third data unit of the memory device using the second read voltage level of the third set of data units.
